(19) United States
(12) Patent Application Publication
(10) Pub. No.: US 2025/0160010 A1
(43) Pub. Date: May 15, 2025

(54) IMAGE SENSOR PIXEL AND METHOD OF MANUFACTURING THE SAME

(71) Applicant: Samsung Electronics Co., Ltd., Suwon-si (KR)

(72) Inventor: Changyong Um, Suwon-si (KR)

(21) Appl. No.: 18/919,602

(22) Filed: Oct. 18, 2024

(30) Foreign Application Priority Data
Nov. 9, 2023 (KR) 10-2023-0154568

(51) Int. Cl. H01L 27/146

(52) U.S. Cl. CPC H10F 39/80373; H10F 39/014; H10F 39/18; H10F 39/8023

(57) ABSTRACT

An image sensor pixel includes a semiconductor substrate including a first surface and a second surface, a photoelectric conversion region between the first surface and the second surface, a floating diffusion region between the first surface and the second surface, and a vertical transfer gate including: a first vertical region and a second vertical region that each include a side surface portion and a lower surface portion, the side surface portion of each of the first vertical region and the second vertical region has a first inclination from the lower surface portion to a first height of the vertical transfer gate relative to the lower surface portion and a second inclination from the first height to a second height of the vertical transfer gate relative to the lower surface portion, and the first height is less than the second height.

### CROSS-REFERENCE TO RELATED APPLICATION

This application is based on and claims priority under 35 U.S.C. § 119 to Korean Patent Application No. 10-2023-0154568, filed on Nov. 9, 2023, in the Korean Intellectual Property Office, the disclosure of which is incorporated by reference herein in its entirety.

### TECHNICAL FIELD

The present disclosure relates to an image sensor pixel and a method of manufacturing the same. More specifically, the present disclosure relates to a structure of a vertical transfer gate (VTG) included in an image sensor pixel.

### BACKGROUND

An image sensor is a semiconductor device that converts an externally incident optical signal into an electrical signal, and generates image information corresponding to the incident optical signal. Recently, with the development of computer and communication industries, the demand for image sensors is increasing in various fields such as digital cameras, camcorders, mobile phones, security cameras, and medical micro cameras.

In particular, a complementary metal-oxide semiconductor (CMOS) image sensor (CIS) using a CMOS has not only enables product miniaturization by integrating analog and digital signal processing circuits on a single chip, but also has low power consumption, and is thereby widely used as an image sensor for mobile products or small products with limited battery capacity.

Recently, to improve the light reception efficiency and photosensitivity of a CIS, a back-side illumination method has been adopted, which receives incident light through a back side of a substrate, and a VTG is used, which increases photocharge transfer efficiency by extending a transfer gate disposed on a front side of the substrate in a depth direction of the substrate to shorten a separation distance between the transfer gate and a photocharge accumulation portion.

However, as the size of an image sensor pixel is reduced, the width of the VTG is reduced, and accordingly, there is a problem in that an effective channel length of the VTG is reduced such that charge transfer capability is reduced.

### SUMMARY

The present disclosure provides a structure of a vertical transfer gate (VTG) capable of improving charge transfer capability.

An image sensor pixel according to the present disclosure is disclosed. The image sensor pixel may include a semiconductor substrate including a first surface and a second surface, a photoelectric conversion region between the first surface and the second surface, a floating diffusion region that is between the first surface and the second surface and is spaced apart from the photoelectric conversion region in a first direction, and a vertical transfer gate that is configured to selectively electrically connect the photoelectric conversion region and the floating diffusion region, where the vertical transfer gate includes: a first vertical region and a second vertical region that are spaced apart from each other and each include a side surface portion and a lower surface portion, the side surface portion of each of the first vertical region and the second vertical region has a first inclination from the lower surface portion to a first height of the vertical transfer gate in the first direction and relative to the lower surface portion and a second inclination from the first height to a second height of the vertical transfer gate in the first direction and relative to the lower surface portion, and the first height is less than the second height.

An image sensor pixel according to the present disclosure is disclosed. The image sensor pixel may include a semiconductor substrate including a first surface and a second surface, a photoelectric conversion region between the first surface and the second surface, a floating diffusion region that is between the first surface and the second surface and is spaced apart from the photoelectric conversion region in a first direction, and a vertical transfer gate that is configured to selectively electrically connect the photoelectric conversion region and the floating diffusion region, where the vertical transfer gate has a fin-shaped structure, and where a side surface portion of the fin-shaped structure has at least two inclinations.

An image sensor pixel is disclosed and includes a semiconductor substrate including a first surface and a second surface, a photoelectric conversion region between the first surface and the second surface, a floating diffusion region that is between the first surface and the second surface and is spaced apart from the photoelectric conversion region in a first direction, and a vertical transfer gate between the first surface and the second surface, where a width of the vertical transfer gate decreases in a second direction that intersects the first direction as the vertical transfer gate extends toward the first surface

A method of manufacturing an image sensor pixel, according to the present disclosure, is disclosed. The method may include forming a first recess region and a second recess region in a semiconductor substrate, performing dry etching by applying a first photoresist to a remaining region excluding a region adjacent to a fin region formed between the first recess region and the second recess region, removing the first photoresist and depositing a first nitride layer, etching a portion of the first nitride layer, depositing an insulator material in the first recess region and the second recess region, and then performing planarization, performing wet etching by applying a second photoresist to the remaining region excluding the region adjacent to the fin region, and forming a VTG in a third recess region formed as a result of completing the wet etching.

### BRIEF DESCRIPTION OF THE DRAWINGS

Embodiments will be more clearly understood from the following detailed description taken in conjunction with the accompanying drawings in which:

FIG. 1 is a block diagram illustrating an image sensor according to some embodiments of the present disclosure;

FIG. 2 is a circuit diagram illustrating a pixel array of an image sensor shown in FIG. 1, according to some embodiments of the present disclosure;

FIG. 3A is a plan view of a pixel according to some embodiments of the present disclosure;

FIG. 3B is a cross-sectional view of a pixel according to some embodiments of the present disclosure;

FIG. 4 is a cross-sectional view of a vertical transfer gate according to some embodiments of the present disclosure;

FIG. 5 is a cross-sectional view for describing a vertical transfer gate and peripheral areas, according to some embodiments of the present disclosure;

FIGS. 6, 7, and 8 are plan views of a pixel according to some embodiments of the present disclosure;

FIGS. 9A, 9B, 9C, 9D, 9E, 9F, 9G, 9H, and 9I are cross-sectional views for describing a method of manufacturing pixels, according to some embodiments of the present disclosure; and

FIG. 10 is a flowchart illustrating a method of manufacturing pixels, according to some embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

Hereinafter, various embodiments of the present disclosure are described with reference to the accompanying drawings.

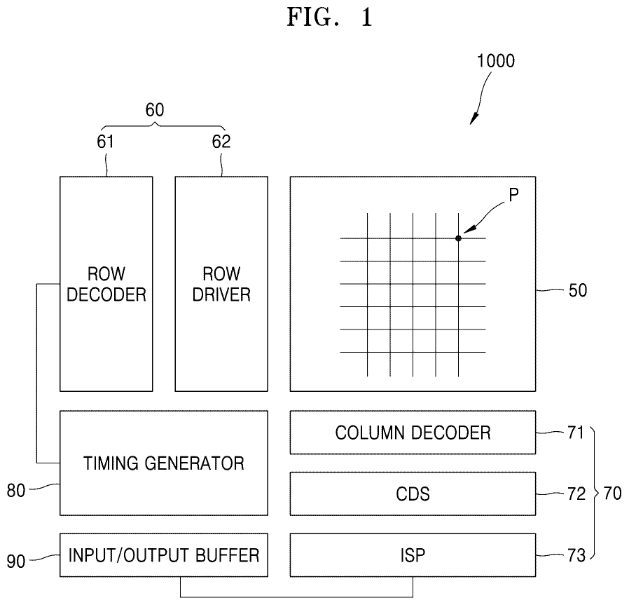

FIG. 1 is a block diagram of an image sensor according to some embodiments. According to an example, the image sensor shown in FIG. 1 is a complementary metal-oxide semiconductor (CMOS) image sensor.

Referring to FIG. 1, an image sensor 1000 according to some embodiments may include a plurality of unit pixels P, a pixel array 50 that converts an incident optical signal into an electrical signal, a first signal unit 60 that includes a row decoder 61 and a row driver 62 and applies a driving signal for each of the unit pixels P to the pixel array 50, a second signal unit 70 that includes a column decoder 71, a correlated double sampler (CDS) 72, and an image signal processor (ISP) 73 and detects, as a detection signal that is data for a video image, an electrical signal of each unit pixel P from the pixel array 50, and a timing generator 80 connected to the first signal unit 60 and the second signal unit 70 to selectively control the driving signal and the detection signal. Referring to FIG. 1, the image sensor 1000 may further include an input/output buffer 90 that stores the detection signal detected from the second signal unit 70.

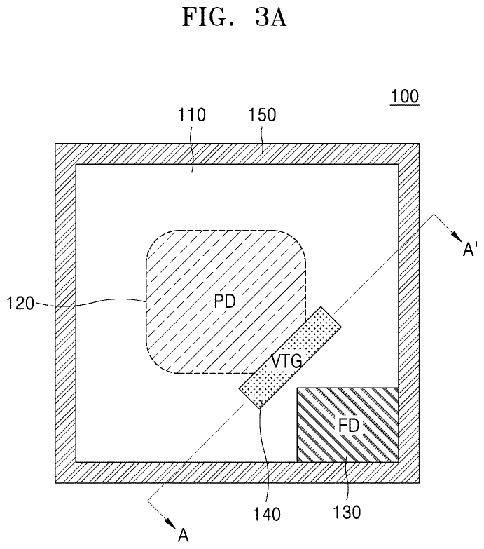

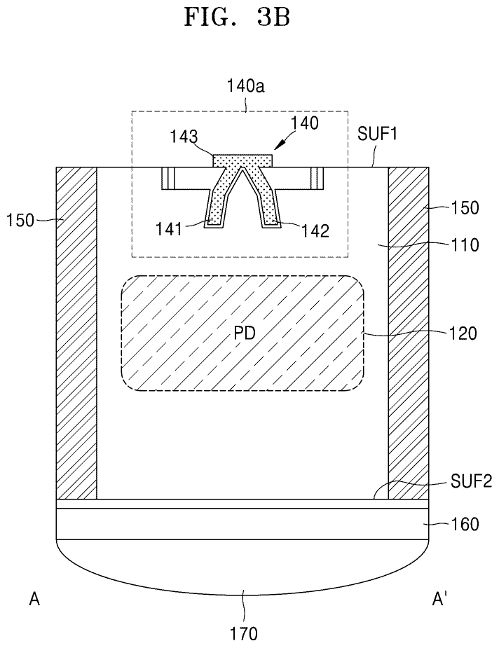

According to an example, the pixel array 50 may include the plurality of unit pixels P that are two-dimensionally arranged in the form of a matrix and convert an optical signal into an electrical signal. At least some of the plurality of unit pixels P according to the present disclosure may include a vertical transfer gate (VTG). At least some of the plurality of unit pixels P according to the present disclosure may include a VTG in the form of a fin structure having two or more different inclinations. As used herein, an inclination may refer to a slope of a given surface. Through this structure, there is an effect of maximizing or enhancing charge transfer capability. A specific structure of a VTG of a unit pixel P is described with reference to FIG. 3A and other drawings.

The pixel array 50 may be driven by a plurality of driving signals, such as a pixel select signal, a reset signal, and a charge transfer signal, transmitted from the row driver 62. In addition, an electrical signal converted from each unit pixel P may be provided to the CDS 72 through the column decoder 71.

The first signal unit 60 may apply driving signals for driving the unit pixels P to the pixel array 50.

According to an example, the first signal unit 60 may include the row decoder 61 that determines a driving row of the unit pixels P arranged in the form of a matrix, and the row driver 62 connected to the row decoder 61 to supply a driving signal to the driving row. Accordingly, the driving signal may be supplied to each row of the pixel array 50.

The second signal unit 70 may detect the electrical signal stored in the unit pixels P. The second signal unit 70 may output image data by detecting the electrical signal stored in the plurality of unit pixels P. According to an example, the second signal unit 70 may include the column decoder 71 that determines a reading column of the unit pixels P arranged in the form of a matrix, the CDS 72 that samples an electrical signal from a unit pixel P corresponding to the reading column, and the ISP 73 that processes image data output from the CDS 72. By double sampling a specific noise level and a detection signal level corresponding to the electrical signal, the CDS 72 may output a difference level that is a difference between a noise level and a detection signal level. The CDS 72 may further include an analog-to-digital converter (ADC) that converts an analog signal, which is an electrical signal, into a digital signal. The ADC may convert an analog signal corresponding to the difference level into a digital signal.

The ISP 73 may be implemented to process image data output from the CDS 72. For example, the ISP 73 may generate image data by performing a signal processing operation, such as color interpolation, color correction, gamma correction, color space conversion, edge correction, etc., on received frame data. The ISP 73 may process the image data to generate a subject image and may transmit the subject image to a display or store the subject image in memory.

The timing generator 80 is electrically connected to the first signal unit 60 and the second signal unit 70 and provides a timing signal to the row decoder 61 and the column decoder 71, and may thereby control a driving row to which a driving signal is applied and a reading column from which a detection signal is detected.

The input/output buffer 90 may store a digital signal transmitted from the second signal unit 70 and sequentially transmit the digital signal to an image signal processing unit (not shown) according to a decoding order in the column decoder 71.

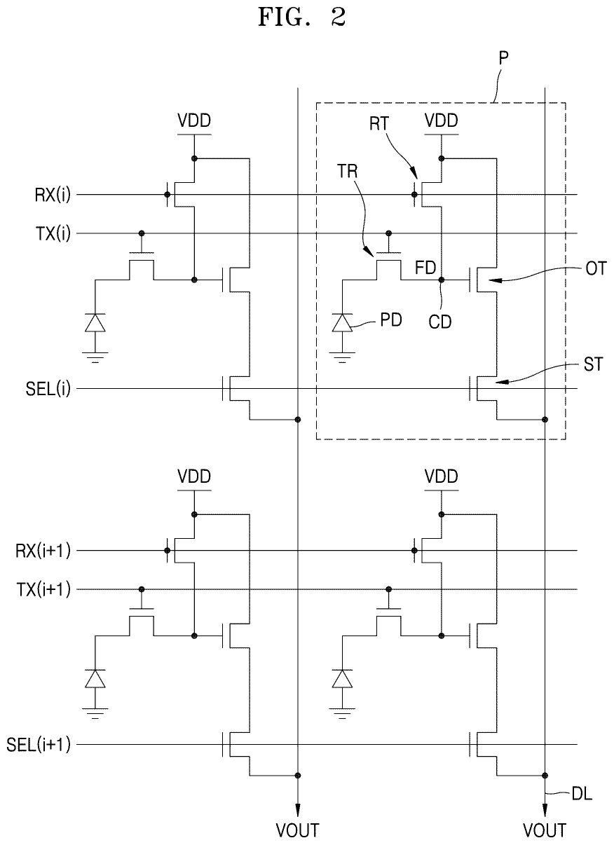

FIG. 2 is a circuit diagram illustrating the pixel array of the image sensor shown in FIG. 1 according to some embodiments. Referring to FIG. 2, the pixel array 50 may include the plurality of unit pixels P arranged in the form of a two-dimensional matrix.

In some embodiments, a unit pixel P may include a photoelectric conversion device PD that receives light and generates and accumulates charge, a transfer transistor TR that transmits a photocharge generated by the photoelectric conversion device PD to a charge detector CD such that the photocharge may be detected, and at least one read transistor that reads video image data by detecting an electrical signal from the charge detector CD.

Referring to FIG. 2, a read transistor may include a reset transistor RT, an output transistor OT, and a selection transistor ST. Each of the transistors may be configured as, for example, a metal oxide silicon (MOS) transistor including MOS.

The configuration of the read transistor may vary depending on the configuration of the image sensor. Referring to FIG. 2, it is shown that the unit pixel P includes one photoelectric conversion device PD and four transistors (TR, RT, OT, and ST), but the unit pixel P may include three transistors or five transistors.

Referring to FIG. 2 again, the photoelectric conversion device PD may generate a photocharge that corresponds to incident light and may accumulate the photocharge therein. In some embodiments, the photoelectric conversion device PD may be a photodiode, a phototransistor, a photogate, a pinned photodiode (PPD), or a combination thereof. Charge accumulated in the photoelectric conversion device PD may be selectively transmitted to the charge detector CD by the transfer transistor TR, and may be detected as an electrical signal related to a video image by operation of the read transistor including the reset transistor RT, the output transistor OT, and the selection transistor ST.

The charge detector CD may include a floating diffusion region doped with n-type impurities in a semiconductor layer. The charge detector CD may receive the charge accumulated in the photoelectric conversion device PD and store the charge cumulatively. In addition, the charge detector CD may be electrically connected to the output transistor OT and control an operation of the output transistor OT.

The transfer transistor TR may selectively transmit the charge accumulated in the photoelectric conversion device PD to the charge detector CD. The transfer transistor TR may be controlled by a charge transfer signal line TX(i) applied through a gate electrode of the MOS transistor. According to an example of the present disclosure, the transfer transistor TR may have a structure of a VTG. According to an example, the structure of the VTG of the transfer transistor TR may be provided as a structure of a dual VTG. In the present disclosure, the dual VTG refers to a VTG that has two vertical regions spaced apart from each other and has a structure that forms a fin-shaped channel. According to an example, vertical regions of the VTG of the transfer transistor TR according to the present disclosure may have a structure having at least two inclinations. Through this structure, capability to transfer charges included in the photoelectric conversion device PD may be improved. Detailed descriptions thereof are described with reference to FIG. 3A and other drawings.

The reset transistor RT may be connected between a node, which supplies a power voltage VDD, and a floating diffusion node FD, which constitutes the charge detector CD, to reset a charge stored in the charge detector CD. For example, the reset transistor RT may include one MOS transistor including a source electrode connected to the charge detector CD and a drain electrode connected to the power voltage VDD. At this time, the reset transistor RT may be driven by a reset signal provided by a reset signal line RX(i). When the reset transistor RT is turned on by the reset signal, the power voltage VDD connected to the drain electrode of the reset transistor RT may be applied to the charge detector CD. Accordingly, when the reset transistor RT is turned on, the charge detector CD may be reset.

The output transistor OT may be combined with a constant current source (not shown) located outside the unit pixel P to constitute a source follower buffer amplifier. The output transistor OT is connected to the floating diffusion node FD of the charge detector CD to amplify a potential change of a charge stored in the charge detector CD, and may convert an amplification value into an output voltage VOUT.

The selection transistor ST is connected between a source and ground of the output transistor OT and may selectively output the output voltage VOUT. The selection transistor ST may select a unit pixel P to be read in row units and transmit, as an image signal, the output voltage VOUT of the selected unit pixel P along a detection line DL in a column direction. For example, the selection transistor ST is driven by a pixel select signal provided by a selection signal line SEL(i), and when the selection transistor ST is turned on, the power voltage VDD connected to a drain electrode of the output transistor OT may be transmitted to a drain electrode of the selection transistor ST.

The signal lines (TX(i), RX(i), and SEL(i)) for respectively driving the transfer transistor TR, the reset transistor RT, and the selection transistor ST may be arranged in the form of a line in a row direction to apply a charge transfer signal, a reset signal, and a pixel select signal to the plurality of unit pixels P at the same time.

As described above, the unit pixel P including the photoelectric conversion device PD, the charge detector CD, and the read transistor may be formed to have a structure as described below on a semiconductor substrate, and in the pixel array 50, the plurality of unit pixels P may be arranged in the form of a matrix in the row direction and the column direction.

FIG. 3A is a plan view of a pixel according to an embodiment. FIG. 3B is a cross-sectional view of a pixel according to an embodiment. FIG. 3B is a cross-sectional view of a VTG 140 of FIG. 3A taken along a line A-A′.

Referring to FIGS. 3A and 3B, an image sensor pixel 100 according to some embodiments may include a semiconductor substrate 110, a photoelectric conversion region 120 formed in the semiconductor substrate 110, a floating diffusion region 130, the VTG 140, and a deep trench isolation (DTI) structure 150. According to some embodiments, the image sensor pixel 100 may further include a color filter 160 and a micro lens 170, and may further include at least one transistor (not shown) for outputting a signal, such as a reset transistor, a drive transistor, a selection transistor, etc. In embodiments shown in the drawings below, the structure of the VTG 140 included in the image sensor pixel 100 may refer to the structure of the gate included in the transfer transistor TR of FIG. 2.

The semiconductor substrate 110 may have a first surface SUF1 and a second surface SUF2 facing the first surface SUF1. In some embodiments, an image sensor including a pixel may be a backside illumination (BSI)-type image sensor.

In this case, the VTG 140 or other transistors are formed on the first surface SUF1 (for example, a front surface) of the semiconductor substrate 110, and incident light may reach the photoelectric conversion region 120 through the second surface SUF2 (for example, a rear surface) of the semiconductor substrate 110. In addition, in some embodiments, the semiconductor substrate 110 may include a semiconductor layer formed through an epitaxial process. In some embodiments, the semiconductor substrate 110 may be formed by doping impurities of a first conductivity type (for example, p-type).

The photoelectric conversion region 120 is formed in the semiconductor substrate 110 and may generate charges (for example, a photocharge) based on incident light. For example, electron-hole pairs are generated in response to the incident light, and the photoelectric conversion region 120 may collect these electrons or holes. For convenience of explanation, FIG. 3B illustrates the photoelectric conversion region 120 as the photodiode PD, but the photoelectric conversion region 120 may include a photodiode, a PPD, a phototransistor, a photogate, or a combination thereof. The photoelectric conversion region 120 may be formed by the photoelectric conversion device PD of FIG. 2.

FIG. 3B illustrates an example in which the photoelectric conversion region 120 is spaced apart from the second surface SUF2 of the semiconductor substrate 110, but according to some embodiments, the photoelectric conversion region 120 may extend to the second surface SUF2 of the semiconductor substrate 110.

The floating diffusion region 130 may be spaced apart from the photoelectric conversion region 120 in the semiconductor substrate 110. Charges generated in the photoelectric conversion region 120 may be transmitted through a channel of the VTG 140 and stored in the floating diffusion region 130. In some embodiments, the floating diffusion region 130 may be formed by doping impurities of a second conductivity type (for example, n-type).

The VTG 140 according to an example of the present disclosure may be formed in a recess extending from the first surface SUF1 of the semiconductor substrate 110 to the inside of the semiconductor substrate 110 and on the first surface SUF1 of the semiconductor substrate 110. According to an example, the VTG 140 may be provided in the form of a dual transfer gate. According to an example, the VTG 140 may be arranged between the photoelectric conversion region 120 and the floating diffusion region 130. A fin structure of the VTG 140 may be arranged to face the floating diffusion region 130.

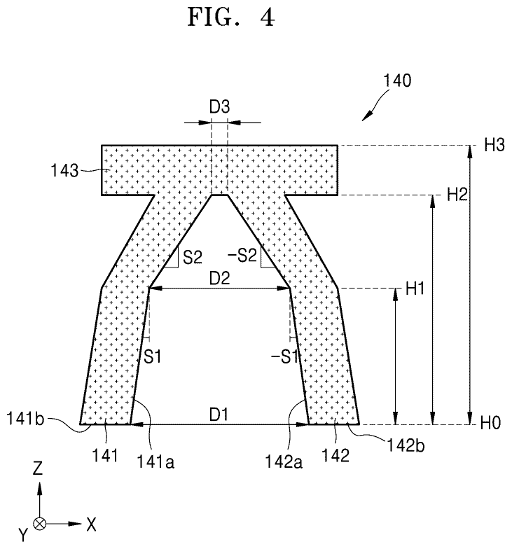

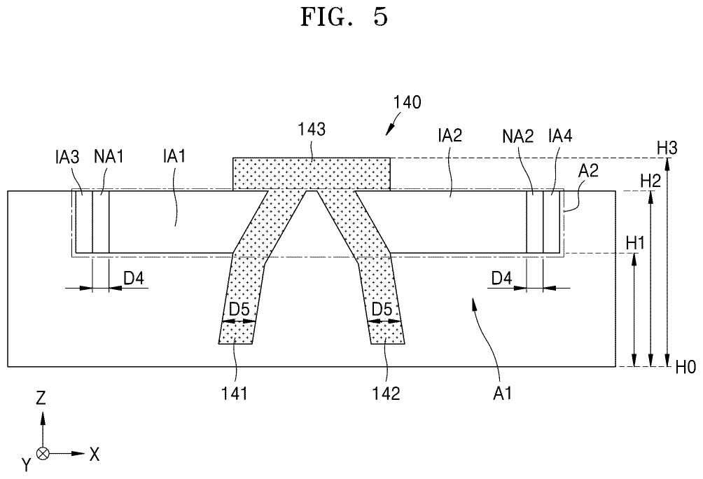

Referring to FIG. 3B, the VTG 140 may include a first vertical region 141 and a second vertical region 142, each extending from the first surface SUF1 to the inside of the semiconductor substrate 110, and a third vertical region 143 extending from the first surface SUF1 to the outside of the semiconductor substrate 110. According to an example, each of the first vertical region 141 and the second vertical region 142 may be formed to have at least two different inclinations. The VTG 140 may form a transfer channel between the photoelectric conversion region 120 and the floating diffusion region 130 in response to a transfer signal, such that charges generated from the photoelectric conversion region 120 are transferred to the floating diffusion region 130. The VTG 140 and a region 140a including a peripheral area surrounding the VTG 140 are described in detail below with reference to FIGS. 4 and 5.

The image sensor pixel 100 may include the DTI structure 150 formed to at least partially surround each image sensor pixel 100. The DTI structure 150 may extend to a certain depth from the first surface SUF1 of the semiconductor substrate 110, or may be formed to completely penetrate or extend into the semiconductor substrate 110 from the first surface SUF1 to the second surface SUF2 of the semiconductor substrate 110. In addition, in some embodiments, the DTI structure 150 may be formed to extend into the semiconductor substrate 110 by a certain depth from the second surface SUF2 of the semiconductor substrate 110, or may be formed to completely penetrate or extend into the semiconductor substrate 110. For example, the DTI structure 150 may include any insulating material, such as silicon oxide (SiOx), silicon nitride (SiNx), hafnium oxide (HfOx), etc. The image sensor pixel 100 is separated from adjacent pixels by the DTI structure 150, and thus, optical and/or electrical crosstalk between pixels may be prevented.

According to another example, the image sensor pixel 100 may include an active region instead of the DTI structure 150 formed to at least partially surround each image sensor pixel 100.

The color filter 160 may be formed on the second surface SUF2 of the semiconductor substrate 110 to correspond to the photoelectric conversion region 120. The color filter 160 may be included in a color filter array arranged in the form of a matrix. In some embodiments, the color filter array may have a Bayer pattern including a red filter, a green filter, and a blue filter. In some embodiments, the color filter array may include a yellow filter, a magenta filter, and a cyan filter. In addition, the color filter array may further include a white filter. In some embodiments, a reflection prevention layer, at least one insulating layer, etc. may be formed between the second surface SUF2 of the semiconductor substrate 110 and the color filter 160.

The micro lens 170 may be formed to correspond to the color filter 160 and the photoelectric conversion region 120. The micro lens 170 may adjust a path of incident light such that the incident light incident on the micro lens 170 may be focused on the photoelectric conversion region 120. In addition, the micro lens 170 may be included in a micro lens array arranged in the form of a matrix.

FIG. 4 is a cross-sectional view of a VTG according to some embodiments. FIG. 5 is a cross-sectional view for describing a VTG and peripheral areas, according to an embodiment.

According to an example, FIG. 4 is a diagram for explaining the structure of the VTG 140 of FIG. 3B in more detail. Referring to FIG. 4, the VTG 140 may include the first vertical region 141, the second vertical region 142, and the third vertical region 143. According to an example, the first vertical region 141 and the second vertical region 142 may be symmetrical to each other. The first vertical region 141 may include a first side surface portion 141a facing the second vertical region 142, and the second vertical region 142 may include a second side surface portion 142a facing the first vertical region 141. The inclinations of the first side surface portion 141a and the second side surface portion 142a from a lowest-end height H0 (e.g., where the lowest-end height H0 corresponds to a height between one of the first or second surfaces SUF1, SUF2 and lower surface portions of the first and second vertical regions 141b, 142b) to a first height H1 (e.g., a first height from the lower surface portions of the first and second vertical regions 141b, 142b) and from the first height H1 to a second height H2 (e.g., a second height from the lower surface portions of the first and second vertical regions 141b, 142b) may be different from each other.

According to an example, the inclination/slope of the first side surface portion 141a from the lowest-end height H0 to the first height H1 (e.g., a lower side surface portion of the first side surface portion 141a) may be S1. The inclination/slope of the first side surface portion 141a from the first height H1 to the second height H2 (e.g., an upper side surface portion of the first side surface portion 141a) may be S2. According to an example, the inclination S1 of the first side surface portion 141a from the lowest-end height H0 to the first height H1 and the inclination S2 of the first side surface portion 141a from the first height H1 to the second height H2 may be different from each other. According to an example, the inclination S1 from the lowest-end height H0 to the first height H1 may be greater than the inclination S2 from the first height H1 to the second height H2. In some embodiments, the inclination S1 may be referred to as a lower-side inclination, and the inclination S2 may be referred to as an upper-side inclination.

According to an example, the inclination of the second side surface portion 142a from the lowest-end height H0 to the first height H1 may be −S1. The inclination of the second side surface portion 142a from the first height H1 to the second height H2 may be −S2. According to an example, the inclination −S1 of the second side surface portion 142a from the lowest-end height H0 to the first height H1 and the inclination −S2 of the second side surface portion 142a from the first height H1 to the second height H2 may be different from each other. According to an example, S1 and S2 may each be a real number that is greater than or equal to zero.

According to an example, an absolute value of the inclination of the first side surface portion 141a from the first height H1 to the second height H2 and an absolute value of the inclination of the second side surface portion 142a from the first height H1 to the second height H2 may each be equal to S2. An absolute value of the inclination of the first side surface portion 141a from the lowest-end height H0 to the first height H1 and an absolute value of the inclination of the second side surface portion 142a from the lowest-end height H0 to the first height H1 may each be equal to S1.

Referring to FIG. 4, the length between the first vertical region 141 and the second vertical region 142 in an X-axis direction at the lowest-end height H0 may be D1. The length between the first vertical region 141 and the second vertical region 142 in the X-axis direction at the first height H1 may be D2. The length between the first vertical region 141 and the second vertical region 142 in the X-axis direction at the second height H2 may be D3. According to an example, D1 may be greater than D2, and D2 may be greater than D3.

In other words, referring to FIG. 4, each side surface portion of the first vertical region 141 and the second vertical region 142 may have different inclinations at different heights, and as each side surface of the first vertical region 141 and the second vertical region 142 extends toward the first surface SF1 in a Z-axis direction, an inclination thereof may be configured to decrease a distance or width between the first vertical region 141 and the second vertical region 142.

As the width decreases from a smallest height to the greatest height of a fin region of a dual VTG, a potential hump decreases, and thus, charge transfer characteristics may be improved. According to the present disclosure, by varying the inclinations of side surface portions of a first vertical transfer region and a second vertical transfer region, a taper angle may increase, thereby improving charge transfer characteristics.

The third vertical region 143 may extend from the first vertical region 141 and the second vertical region 142 in the Z-axis direction. The third vertical region 143 may connect the first vertical region 141 and the second vertical region 142 to each other. The length of the third vertical region 143 in the Z-axis direction may be a value obtained by subtracting the second height H2 from a third height H3 (e.g., a third height from the lower surface of the first and second vertical regions 141b, 142b). According to an example, H0, H1, H2, and H3 may each be a real number of 0 or more.

Referring to FIG. 5, the VTG 140 and its peripheral area are shown. A region shown in FIG. 5 may correspond to the VTG 140 shown in FIG. 3B and the region 140a including a peripheral area surrounding the VTG 140.

In the present disclosure, a region at least partially surrounding the VTG 140 between the first height H1 and the second height H2 is referred to as a second peripheral area A2, and a region at least partially surrounding the VTG 140 between the lowest-end height H0 and the first height H1 is referred to as a first peripheral area A1. According to an example, the second peripheral area A2 may be at least partially surrounded by the first peripheral area A1. The first peripheral area A1 may be a portion of the semiconductor substrate 110. The first peripheral area A1 and the second peripheral area A2 may include different materials.

According to an example, the second peripheral area A2 may include insulator regions IA1, IA2, IA3, and IA4 and nitride regions NA1 and NA2, which are each between the first height H1 and the second height H2. According to an example, the nitride regions NA1 and NA2 may be spaced apart from each other. According to an example, the nitride regions NA1 and NA2 may each include SiN. According to an example, the nitride regions NA1 and NA2 may be spaced apart from each of the first vertical region 141 and the second vertical region 142 of the VTG 140. The nitride regions NA1 and NA2 may be regions including nitride. The insulator regions IA1, IA2, IA3, and IA4 may be regions including an insulator. According to an example, the insulator regions IA1, IA2, IA3, and IA4 may each include oxide. According to an example, the nitride region NA1 may be arranged to be in contact with the insulator region IA1 that is in contact with the first vertical region 141. The nitride region NA2 may be arranged to be in contact with the insulator region IA2 that is in contact with the second vertical region 142.

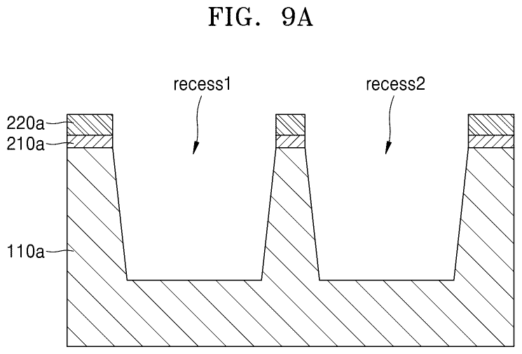

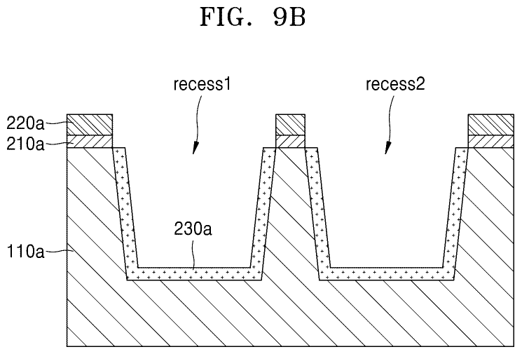

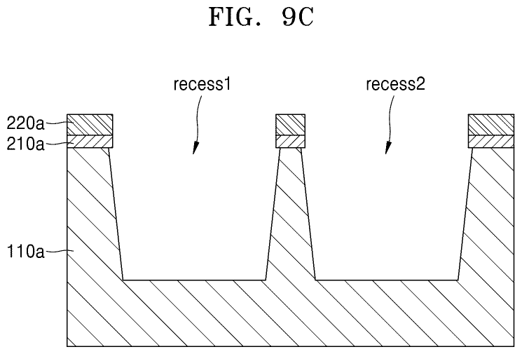

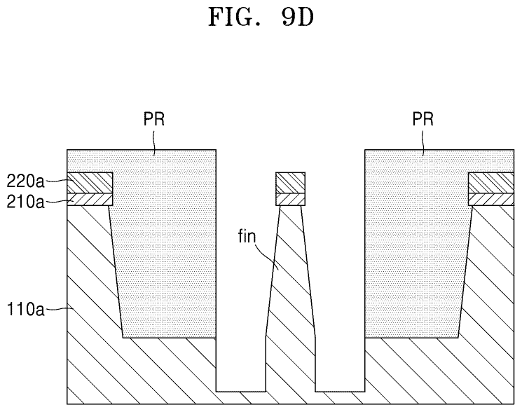

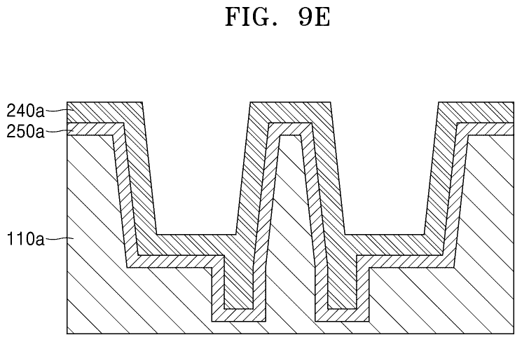

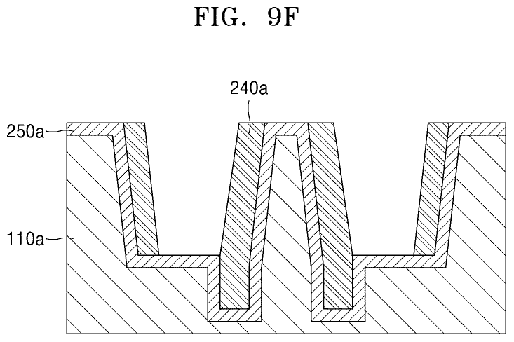

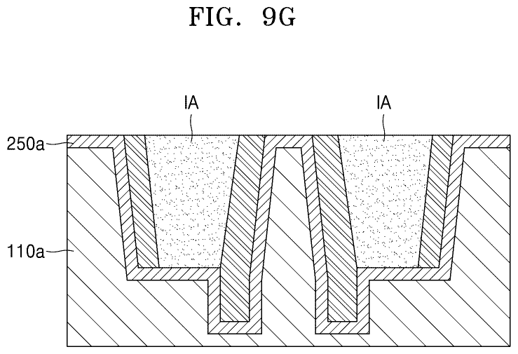

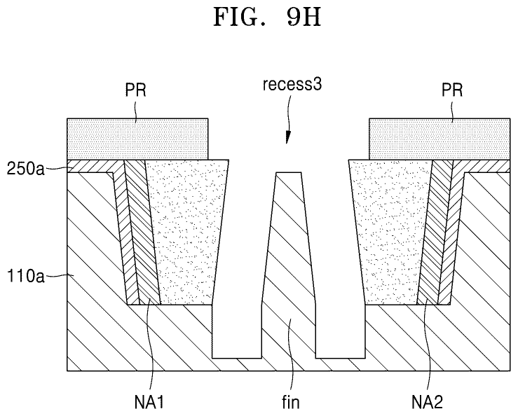

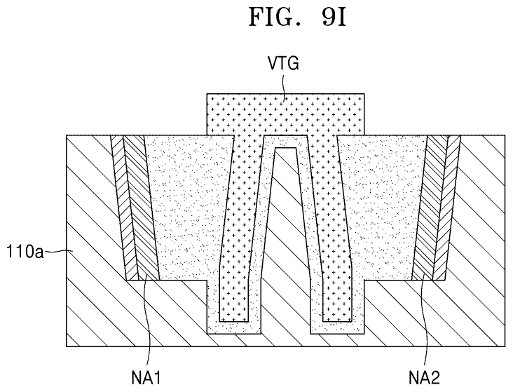

Each of the first vertical region 141 and the second vertical region 142 of the VTG 140 according to the present disclosure may include a dual or plural slope structure. A thickness D5 of the first vertical region 141 and the second vertical region 142 of the VTG 140 according to the present disclosure may be equal to a thickness D4 of the nitride regions NA1 and NA2 formed in the peripheral area. Descriptions thereof are provided in more detail with reference to FIG. 9.

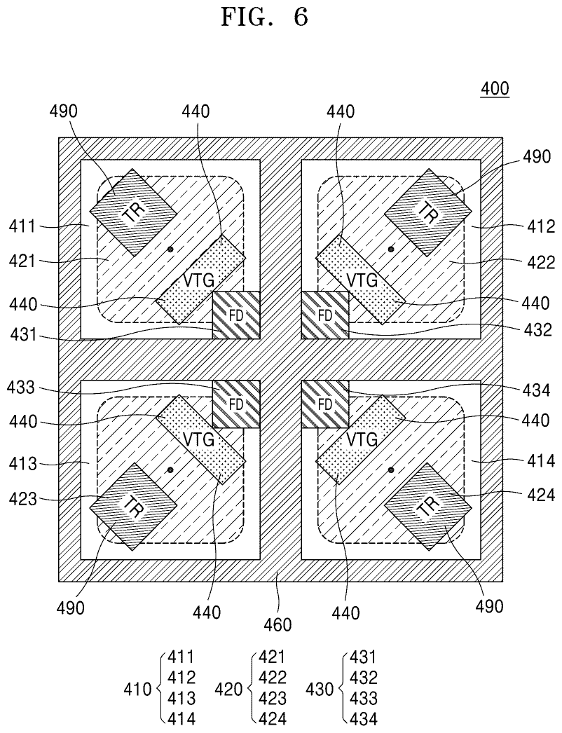

FIGS. 6 to 8 are plan views of a pixel according to embodiments.

VTGs included in pixels according to embodiments of FIGS. 6 to 8 may be provided to have a structure of a dual VTG. The structures and characteristics of dual VTGs are as described above, and thus, cross-sectional views thereof are not provided, and plan views of various pixel structures to which a dual VTG having at least two different inclinations may be applied are described below.

An image sensor pixel 400 of FIG. 6 may have a structure in which four image sensor pixels 100 of FIG. 3A are combined. Referring to FIG. 6, the image sensor pixel 400 has a 2*2 pixel structure that is symmetrical with respect to a center thereof.

The image sensor pixel 400 of FIG. 6 may include four semiconductor substrates 411, 412, 413, and 414, four photoelectric conversion regions 421, 422, 423, and 424, four floating diffusion regions 431, 432, 433, and 434, four dual VTGs 440, a DTI structure 460, and four transistors 490. Each of the dual VTGs 440 may include a first vertical region and a second vertical region, which are spaced apart from each other, and each of the first vertical region and the second vertical region may have at least two different inclinations.

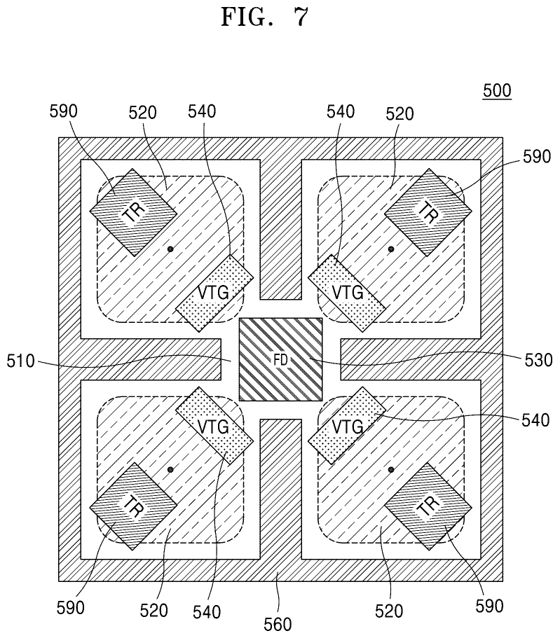

An image sensor pixel 500 of FIG. 7 may include one semiconductor substrate 510, four photoelectric conversion regions 520, one floating diffusion region 530, four VTGs 540, a DTI structure 560, and four transistors 590. The image sensor pixel 500 of FIG. 7 may have a 4PD structure sharing the semiconductor substrate 510 by partially removing a center portion of the DTI structure 460 from the image sensor pixel 400 of FIG. 6. The image sensor pixel 500 of FIG. 7 may have a structure in which the four floating diffusion regions 431, 432, 433, and 434, which are separated in FIG. 6, are mixed into the one floating diffusion region 530.

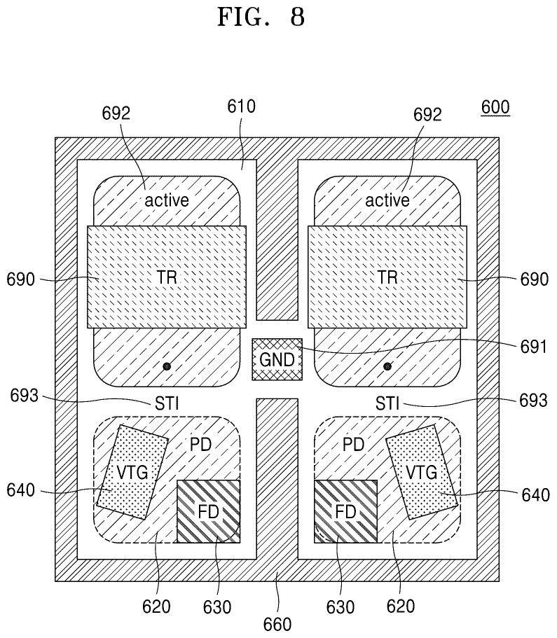

An image sensor pixel 600 of FIG. 8 may be a plan view showing a structure of an image sensor pixel including two photodiodes. The image sensor pixel 600 of FIG. 8 may include one semiconductor substrate 610, two photoelectric conversion regions 620, two floating diffusion regions 630, two VTGs 640, a DTI structure 660, different transistors 690, active regions 692 of the different transistors 690, and shallow trench isolation (STI) regions 693, and a ground region 691. At this time, the different transistors 690 may be any one of a selection transistor, a driving transistor, and an output transistor. The DTI structure 660 may not completely separate the two photodiodes, and the ground region 691 may be arranged between the two photoelectric conversion regions 620 corresponding the two photodiodes. The active regions 692 and the two photoelectric conversion regions 620 may be separated from each other.

According to some embodiments, in the structures of various pixels including a VTG, the structure of a dual VTG may be applied. The inclination of a side surface portion of the dual VTG may decrease toward an upper surface thereof. Accordingly, a transfer path for electrons moving from a photoelectric conversion region to a floating diffusion node may be secured, and charge transfer capability may be improved.

The structure of a pixel including a VTG according to the present disclosure may be applied to either a 2-stack structure or a 3-stack structure.

FIGS. 9A to 9I are cross-sectional views for describing a method of manufacturing pixels according to embodiments.

Referring to FIG. 9A, an embodiment in which a first recess region recess1 and a second recess region recess2 are formed in a semiconductor substrate 110a is disclosed. A mask pattern for forming the first recess region recess1 and the second recess region recess2 may be formed on the semiconductor substrate 110a, and the first recess region recess1 and the second recess region recess2 may be formed by etching, based on the mask pattern, the semiconductor substrate 110a. Referring to FIG. 9A, a first oxide layer 210a and a first nitride layer 220a may be formed on a surface of the semiconductor substrate 110a, which excludes the first recess region recess1 and the second recess region recess2. According to an example, the first oxide layer 210a and the first nitride layer 220a may be a mask pattern for forming the first recess region recess1 and the second recess region recess2.

Referring to FIG. 9B, a second oxide layer 230a may be formed in the first recess region recess1 and the second recess region recess2.

Referring to FIG. 9C, the second oxide layer 230a formed on surfaces of the first recess region recess1 and the second recess region recess2 may be subjected to wet etching. Accordingly, the surfaces of the first recess region recess1 and the second recess region recess2 may be processed to be smoother.

Referring to FIG. 9D, a photoresist PR is applied to a partial region of each of the first recess region recess1 and the second recess region recess2, and a region in which the photoresist PR is not applied may be subjected to dry etching. Accordingly, a lower surface of a fin region fin formed between the first recess region recess1 and the second recess region recess2 may be etched. Accordingly, while the maximum height of the fin region fin is maintained, the lower surface of the fin region fin may be etched.

Referring to FIG. 9E, the applied photoresist PR is removed, and a second oxide layer 250a and a second nitride layer 240a may be deposited over the entire region. Referring to FIG. 9E, the second nitride layer 240a may be deposited such that it is relative thicker. According to an example, the thickness of the second nitride layer 240a may be equal to or greater than the thickness of each of a first vertical region and a second vertical region of a VTG to be formed later.

Referring to FIG. 9F, isotropic wet etching may be performed such that the second nitride layer 240a on an upper side of the fin region fin rather than a side surface portion of the fin region fin is etched. Accordingly, the second nitride layer 240a is maintained on a side surface portion of the fin region fin and side surface portions of the first and second recess regions recess1 and recess2, and the second oxide layer 250a may be exposed through an upper surface of the fin region fin.

Referring to FIG. 9G, an insulator material IA may be deposited in the first recess region recess1 and the second recess region recess2, and an upper surface of the semiconductor substrate 110a may be planarized. According to an example, the insulator material IA may be an insulator material that does not include nitride. According to an example, the insulator material IA may include oxide.

Referring to FIG. 9H, the photoresist PR is applied to cover or overlap the nitride regions NA1 and NA2 to protect the nitride regions NA1 and NA2 on side surfaces of the first recess recess1 and the second recess recess2, and wet etching for etching nitride located on the side surface portion of the fin region fin may be performed. Accordingly, the nitride located on the side surface portion of the fin region fin and the side surface portion of the fin region fin are etched, and thus, a side surface portion having two different inclinations may be formed.

Referring to FIG. 9I, a VTG may be formed to fill or be in a third recess region recess3 formed in FIG. 9H. According to an example, after the VTG is formed, the photoresist PR is removed, and thus, the VTG may be formed to protrude or extend from a first surface of the semiconductor substrate 110a.

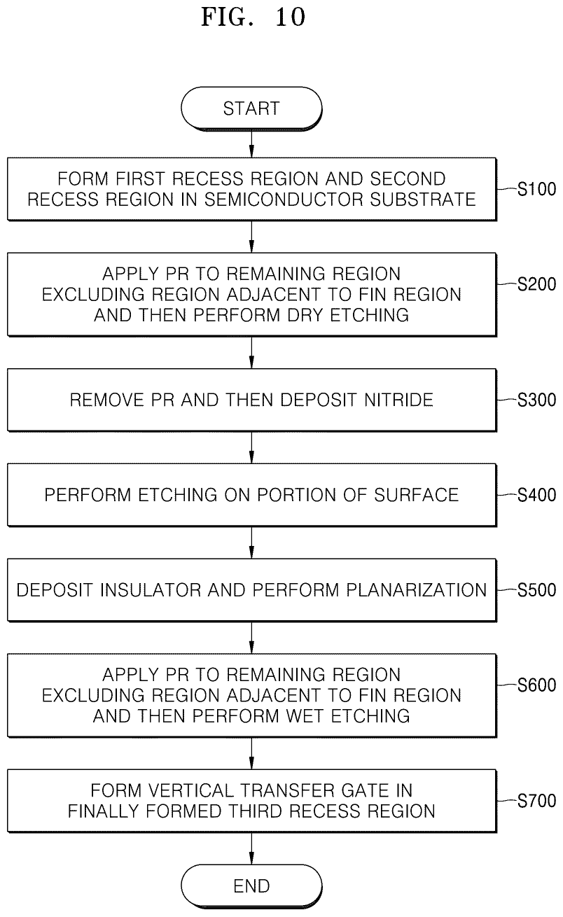

FIG. 10 is a flowchart illustrating a method of manufacturing pixels according to some embodiments.

Referring to operation S100, a first recess region and a second recess region may be formed in a semiconductor substrate, which may be an operation corresponding to FIG. 9A. The first recess region and the second recess region are formed to be adjacent to each other, and may be formed to have the same depth and the same width.

Referring to operation S200, the photoresist PR may be applied to a remaining region excluding a region adjacent to a fin region, and the remaining region may be subjected to dry etching, which may be an operation corresponding to FIG. 9D. The fin region may refer to a fin-shaped region formed between the first recess region and the second recess region. Referring to operation S200, a photoresist may be applied such that regions within a certain distance from the fin region may be etched. Through operation S200, a region having a greater depth than the first recess region and the second recess region may be etched. According to an example, through operation S200, a recess region corresponding to a region from the lowest-end height H0 of the first and second vertical regions of FIG. 4 to the first height H1 may be formed.

Referring to operation S300, the photoresist PR deposited in operation S200 is removed, and then, nitride may be deposited, which may be an operation corresponding to FIG. 9E. According to an example, the thickness of the nitride deposited in the corresponding operation may be equal to or greater than the thickness of each of the first vertical region and the second vertical region of the VTG.

Referring to operation S400, a portion of the nitride deposited on a surface of the semiconductor substrate may be subjected to wet etching, which may be an operation corresponding to FIG. 9F.

In operation S500, an insulator may be deposited on an empty portion, and planarization may be performed, which may be an operation corresponding to FIG. 9G.

In operation S600, the photoresist PR may be applied to a remaining region excluding a region adjacent to the fin region, and then, wet etching may be performed, which may be an operation corresponding to FIG. 9H. Through operation S600, a recess region corresponding to the inclination of each of the first and second vertical regions of FIG. 4 from the first height H1 to the second height H2 may be formed, and a recess region corresponding to the inclination thereof from the lowest-end height H0 to the first height H1 may also be formed.

In operation S700, a VTG may be formed in a third recess region. The third recess region may refer to a recess region having at least two inclinations, which is formed according to a result of performing wet etching in operation S600.

According to a comparative example, due to pixel miniaturization, an increase in fin aspect ratio of a dual VTG structure was required, but due to a decrease in process margin, a dual VTG with a reduced fin height was provided. However, when the height of a fin is reduced, charge transfer performance deteriorated, interfacial degradation due to etching of a top surface of the fin occurred, and deterioration due to an increase in coupling capacitance due to an increase in contact area between a VTG and a floating diffusion region occurred. According to the present disclosure, a structure of a dual VTG may be miniaturized according to pixel shrink, and a method of manufacturing the image sensor pixel including the dual VTG. According to the present disclosure, a fin taper angle and top corner rounding of a dual VTG is increased, and thus, charge transfer characteristics may be improved.

According to the present disclosure, scaling of a dual VTG is advantageous, charge transfer characteristics are excellent or improved, and parasitic capacitance of a floating diffusion node may be reduced or inhibited.

While the present disclosure has been particularly shown and described with reference to example embodiments thereof, it will be understood that various changes in form and details may be made therein without departing from the spirit and scope of the following claims.

1. An image sensor pixel comprising:
a semiconductor substrate comprising a first surface and a second surface;
a photoelectric conversion region between the first surface and the second surface;
a floating diffusion region that is between the first surface and the second surface and is spaced apart from the photoelectric conversion region in a first direction; and
a vertical transfer gate that is configured to selectively electrically connect the photoelectric conversion region and the floating diffusion region,
wherein the vertical transfer gate comprises:
a first vertical region and a second vertical region that are spaced apart from each other and each comprise a side surface portion and a lower surface portion,
the side surface portion of each of the first vertical region and the second vertical region has a first inclination from the lower surface portion to a first height of the vertical transfer gate in the first direction and relative to the lower surface portion and a second inclination from the first height to a second height of the vertical transfer gate in the first direction and relative to the lower surface portion, and
the first height is less than the second height.

2. The image sensor pixel of claim 1, wherein the first inclination is greater than the second inclination.

3. The image sensor pixel of claim 1, wherein:
the first vertical region and the second vertical region are spaced apart from each other by a first distance in a second direction at the first height,
the first vertical region and the second vertical region are spaced apart from each other by a second distance in the second direction at the second height, and
the second direction intersects the first direction.

4. The image sensor pixel of claim 3, wherein the first distance is greater than the second distance.

5. The image sensor pixel of claim 1, wherein the vertical transfer gate has a third height in the first direction and relative to the lower surface portion that is greater than the first height and the second height, and wherein the vertical transfer gate further comprises a third vertical region that electrically connects the first vertical region and the second vertical region to each other.

6. The image sensor pixel of claim 5, wherein the first vertical region, the second vertical region, and the third vertical region comprise a same material.

7. The image sensor pixel of claim 5, further comprising:
a first peripheral area between the lower surface portion and the first height of the vertical transfer gate; and
a second peripheral area between the first height and the second height of the vertical transfer gate,
wherein the second peripheral area comprises an insulator region and a nitride region.

8. The image sensor pixel of claim 7, wherein the nitride region is spaced apart from each of the first vertical region and the second vertical region of the vertical transfer gate in a second direction that intersects the first direction.

9. The image sensor pixel of claim 7, wherein the nitride region, the first vertical region, and the second vertical region have a same thickness in the first direction.

10. The image sensor pixel of claim 7, wherein the first peripheral area and the semiconductor substrate comprise a same material.

11. An image sensor pixel comprising:
a semiconductor substrate comprising a first surface and a second surface;
a photoelectric conversion region between the first surface and the second surface;
a floating diffusion region that is between the first surface and the second surface and is spaced apart from the photoelectric conversion region in a first direction; and
a vertical transfer gate that is configured to selectively electrically connect the photoelectric conversion region and the floating diffusion region,
wherein the vertical transfer gate has a fin-shaped structure, and
wherein a side surface portion of the fin-shaped structure has at least two inclinations.

12. The image sensor pixel of claim 11, wherein the side surface portion comprises a lower side surface portion having a lower-side inclination and an upper side surface portion having an upper-side inclination that is less than the lower-side inclination.

13. The image sensor pixel of claim 11, wherein a width of the fin-shape structure in a second direction that intersects the first direction decreases as the fin-shape structure extends toward the first surface.

14. The image sensor pixel of claim 11, further comprising a first peripheral area and a second peripheral area that at least partially surround the vertical transfer gate, wherein:
the first peripheral area at least partially surrounds the second peripheral area, and
the first peripheral area and the second peripheral area comprise different materials.

15. The image sensor pixel of claim 14, wherein the second peripheral area comprises a nitride region and an insulator region.

16. The image sensor pixel of claim 15, wherein the nitride region is spaced apart from the vertical transfer gate in a second direction that intersects the first direction.

17. The image sensor pixel of claim 15, wherein the nitride region and a vertical region of the fin-shaped structure have a same thickness in the first direction.

18. A method of manufacturing an image sensor pixel, the method comprising:
forming a first recess region and a second recess region in a semiconductor substrate, wherein the first recess region and the second recess region are separated by a fin region;
applying a first photoresist to the first recess region and the second recess region, wherein the first photoresist does not contact the fin region;
removing the first photoresist and depositing a first nitride layer;
etching a first portion of the first nitride layer, depositing an insulator material in the first recess region and the second recess region, and then performing planarization;
applying a second photoresist to the first nitride layer and the insulator material;
etching a second portion of the first nitride layer and the insulator material to form a third recess region; and
forming a vertical transfer gate in the third recess region.

19. The method of claim 18, wherein the first nitride layer has a thickness that is greater than or equal to a thickness of a first vertical region and a second vertical region of the vertical transfer gate.

20. The method of claim 18, wherein the first recess region and the second recess region have a same depth and a same width.

21-23. (canceled)
